(19) United States
(12) Patent Application Publication
(10) Pub. No.: US 2026/0358420 A1
(43) Pub. Date: Nov. 12, 2026

(54) RECOGNITION-ENHANCED BATTERY MANAGEMENT SYSTEM

(71) Applicant: Jonathan Washburn, Austun, TX (US)

(72) Inventor: Jonathan Washburn, Austun, TX (US)

(21) Appl. No.: 19/571,182

(22) Filed: Mar. 18, 2026

Related U.S. Application Data
(63) Continuation-in-part of application No. 19/288,355, filed on Aug. 1, 2025.
(60) Provisional application No. 63/774,229, filed on Mar. 19, 2025.

(51) Int. Cl. G01R 31/36; G01R 31/388; G01R 31/389; G01R 31/392; H01M 10/613; H01M 10/633

(52) U.S. Cl. CPC G01R 31/3648; G01R 31/388; G01R 31/389; G01R 31/392; H01M 10/613; H01M 10/633

(57) ABSTRACT

A recognition-enhanced battery management system employs recognition-based control to regulate charging, discharging, and thermal management of a battery pack using measured operating parameters including voltage, current, temperature, and impedance. A controller processes measurement data to determine state-of-charge and state-of-health and to generate control outputs for charge control, discharge control, and thermal management. In some embodiments, the controller implements a recognition subsystem architecture including a Recognition Charging Control subsystem, a Recognition Discharging Control subsystem, a Recognition Thermal Management subsystem, a state-of-charge/state-of-health estimator, a Recognition State-of-Health Degradation Scoring subsystem, and a Recognition Adaptive Parameter Tuning subsystem. The system may further generate degradation-related outputs and updated operating limits for later control intervals, thereby supporting adaptive battery management across vehicle, residential-storage, portable-electronics, and grid-storage applications.

### CROSS-REFERENCE TO RELATED APPLICATIONS

This application is a continuation-in-part of U.S. Nonprovisional patent application Ser. No. 19/288,355, filed Aug. 1,2025, which claims the benefit of U.S. Provisional Patent Application No. 63/774,229, filed Mar. 19, 2025, titled “Recognition-Enhanced Battery Management System”.

### FEDERALLY SPONSORED RESEARCH AND DEVELOPMENT

Not Applicable.

### JOINT RESEARCH AGREEMENT

Not Applicable.

### REFERENCE TO A “SEQUENCE LISTING”, A TABLE, OR A COMPUTER PROGRAM LISTING APPENDIX SUBMITTED ON A COMPACT DISC AND AN INCORPORATION-BY-REFERENCE OF THE MATERIAL ON THE COMPACT DISC

Not Applicable.

### FIELD OF THE INVENTION

The present invention pertains to battery-management systems for rechargeable electrochemical energy-storage packs, including, but not limited to, those used in electric vehicles, stationary storage systems, grid-connected storage systems, portable electronics, and other battery-powered applications, and, more particularly, to a recognition-enabled hardware-and-software architecture configured to dynamically regulate charging, discharging, and thermal-management operations in real time, determine battery state information, generate degradation-related evaluations, and adapt operating limits to support battery longevity, efficiency, and safety.

### BACKGROUND OF THE INVENTION

Rechargeable battery packs, including lithium-ion, lithium-iron-phosphate, and other electrochemical energy-storage systems, may experience capacity fade, increased internal resistance, thermal stress, and reduced service life when operated outside preferred charging, discharging, and temperature conditions. In many applications, battery-management systems rely on fixed voltage, current, and temperature thresholds that may not adequately account for changing state-of-charge, state-of-health, degradation trends, chemistry-specific behavior, or dynamic operating conditions.

Accordingly, improved battery-management approaches are needed that can use measured battery conditions to more adaptively regulate charging, discharging, thermal management, and related control parameters. Improved approaches are also needed for evaluating battery health and adjusting operating limits over time in a manner that supports battery longevity, efficiency, and safety.

### SUMMARY OF THE INVENTION

The present invention provides a recognition-enhanced battery management system configured to regulate charging, discharging, and thermal-management operations of a battery pack using measured operating parameters including voltage, current, temperature, and impedance. In some embodiments, a controller receives measurement data, determines state-of-charge and state-of-health, evaluates one or more recognition-based control relationships, and generates control outputs that adjust battery operation to reduce electrochemical and thermal stress. In some embodiments, the controller further implements a recognition subsystem architecture including a Recognition Charging Control subsystem, a Recognition Discharging Control subsystem, a Recognition Thermal Management subsystem, a state-of-charge/state-of-health estimator, a Recognition State-of-Health Degradation Scoring subsystem, and a Recognition Adaptive Parameter Tuning subsystem. The system may generate degradation-related outputs and updated operating limits for later control intervals, thereby supporting adaptive battery management across vehicle, stationary-storage, portable-electronics, and other rechargeable energy-storage applications.

### BRIEF DESCRIPTION OF THE DRAWINGS

FIG. 1 High-level system architecture of the REBMS.

FIG. 2 Flow diagram of dual-channel recognition inference.

FIG. 3 Circuit schematic showing adaptive balancing network.

FIG. 4 User interface for predictive state-of-health display.

FIG. 5 Mathematical coverage function Fcov(x)=x/(x+χ).

FIG. 6 Optimal charging-current equation I_chg(t).

FIG. 7 Optimal discharging-current equation I_dis(t).

FIG. 8 Cooling-control equation T_cool(t).

FIG. 9 Adaptive χ-update equation.

FIG. 10 is a block diagram of an embodiment of a recognition subsystem architecture for a recognition-enhanced battery management system, showing a Recognition Physics Controller implementing recognition charging control, recognition discharging control, recognition thermal management, state-of-charge/state-of-health estimation, recognition state-of-health degradation scoring, and recognition adaptive parameter tuning.

### REFERENCE NUMERALS

100 Battery pack comprising a plurality of electro-chemical cells.
110 Sensor array measuring cell voltage, pack current, temperature, and impedance.
120 16-bit delta-sigma metrology chain phase-locked to tick τ₀.
130 Recognition Physics Controller (RPC) implemented on an ARM Cortex-M7 micro-controller.
140 Power-stage actuators (charger, inverter, PWM fan or pump drivers).
150 Communications interface (CAN bus transceiver and ESP32 MQTT/cloud gateway).
200 Firmware flow executing Steps 1-8 of the Universal Ledger Algorithm.
300 Adaptive balancing network schematic.
400 User dashboard for predictive state-of-health display.
1000 Recognition subsystem architecture
1010 Recognition Charging Control (RCC) subsystem
1020 Recognition Discharging Control (RDC) subsystem
1030 Recognition Thermal Management (RTM) subsystem
1040 State-of-charge/state-of-health estimator
1050 Recognition SOH Degradation Scoring (RDS) subsystem
1060 Recognition Adaptive Parameter Tuning (RAPT) subsystem
1070 Charge-control command output
1080 Discharge-control command output
1090 Thermal-management command output
1100 Alert/maintenance/health output
1110 Updated SOC operating limits
1120 External analytics/fleet/cloud interface

### DETAILED DESCRIPTION OF THE INVENTION

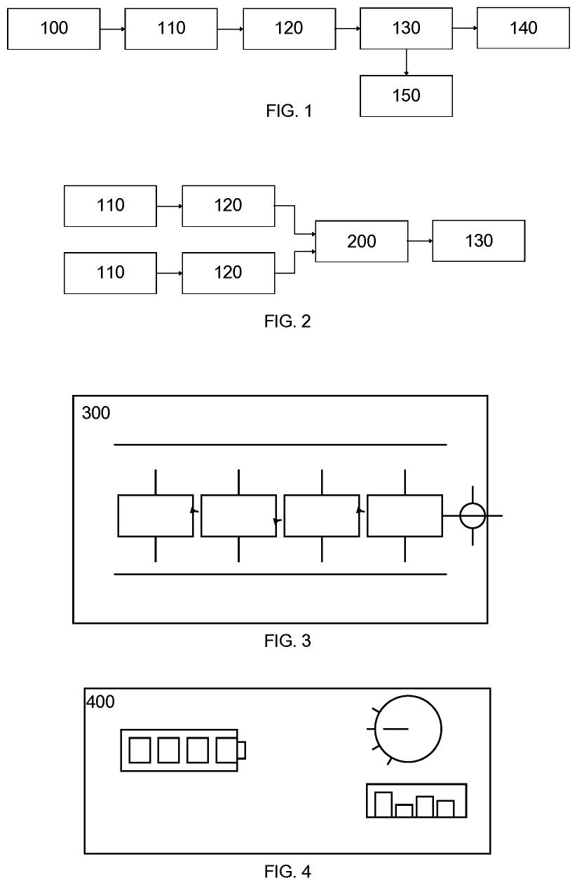

### 1. System Architecture (FIG. 1)

The REBMS comprises: (i) a battery pack (100) containing multiple cells; (ii) precision sensors (110) measuring voltage, current, temperature, and impedance; (iii) a 16-bit delta-sigma metrology chain (120) phase-locked to multiples of τ₀; (iv) a Recognition Physics Controller (130) on an ARM Cortex-M7 micro-controller; (v) power-stage actuators (140); and (vi) a communications interface (150).

### 2. Recognition Coverage Function

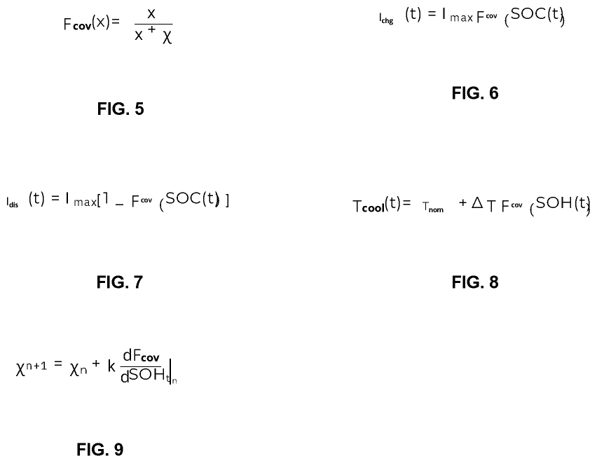

The optimisation kernel is defined by FIG. 5. Charging, discharging, and cooling control laws are shown respectively in FIGS. 6-8.

### 3. Adaptive Learning

Once per day the RPC updates χ according to the adaptive rule illustrated in FIG. 9, ensuring life-long optimisation without empirical tuning.

### 4. Implementation Details

Sensor acquisition uses 16-bit delta-sigma ADCs at 128 kS s⁻¹ with isolated front-ends.
Firmware executes recognition updates every N×8τ₀; watchdogs enforce fault safety within 500 μs.
Thermal management drives PWM fans or BLDC pumps; χ modulates T(nom) while PID gains remain fixed.
An ESP32 gateway streams MQTT telemetry (~2 kB min⁻¹) and accepts signed χ updates OTA.

### 5. Exemplary Embodiment

In a 48 V, 200 Ah LiFePO₄ residential pack the REBMS samples sensors at 10 Hz and applies the above control laws, achieving 34% longer life to 80% SOH and a 30% reduction in peak ΔT versus commercial controllers.

By way of example, consider a residential lithium iron phosphate battery pack having SOCmax set to 0.95 and SOC(t)=0.85 during charging. In some embodiments, a charge headroom may be determined as Hchg=SOCmax−SOC(t)=0.10, and a normalized input may be determined as xchg=Hchg/SOCmax≈0.105. Using the recognition coverage function of FIG. 5, the controller computes a coverage value Fcov(xchg) and scales a maximum allowed charge current Imax accordingly, thereby reducing charging aggressiveness as SOC(t) approaches SOCmax while maintaining smooth control behavior.

By further example, if the estimator indicates SOH(t)=0.80, then (1−SOH(t))=0.20, and the degradation scoring subsystem may compute Dscore=Fcov(0.20) and compare Dscore to one or more stored threshold bands to generate an alert or maintenance-related output. In some embodiments, when Dscore exceeds a stored threshold, the adaptive parameter tuning subsystem refines at least one operating limit (e.g., reducing SOCmax and/or increasing SOCmin within stored bounds) for subsequent operating intervals to reduce stress and improve longevity.

### 6. Further Embodiments

In further embodiments, the recognition-enhanced battery management system disclosed herein may be implemented using the previously described overall system architecture while incorporating additional functional organization and expanded control features. For example, and with continued reference to FIG. 1, the system may continue to include a battery pack (100) comprising a plurality of electrochemical cells, a sensor suite (110) configured to measure one or more pack or cell operating parameters, a metrology chain (120) configured to condition and digitize measured signals, a Recognition Physics Controller (RPC) (130) configured to execute recognition-based control logic, one or more power-stage actuators (140) configured to effect charging, discharging, and thermal-management operations, and a communications interface (150) configured to support local and/or remote data exchange. In such embodiments, the additional features described below may be implemented without requiring replacement of the previously described REBMS framework, and may instead be incorporated as further embodiments, extensions, refinements, or alternative implementations of that framework.

In some embodiments, the recognition-based control functionality executed by the RPC (130) may be organized into a plurality of cooperating functional subsystems while remaining within the same overall REBMS architecture. Such subsystem partitioning may be used to separate charging-related decision logic, discharging-related decision logic, thermal-management decision logic, health-evaluation logic, and adaptive tuning logic into distinct functional blocks for clarity of implementation, computational efficiency, modular verification, or deployment flexibility. In some embodiments, such partitioning may be logical only, such that multiple subsystems are executed by a common processor and memory within the RPC (130). In other embodiments, one or more such subsystems may be implemented as separate firmware modules, separate processing threads, separate safety partitions, dedicated hardware accelerators, coprocessors, field-programmable logic, or distributed controller elements communicating over one or more internal or external buses. Accordingly, the subsystem organization described in the appended embodiments should be understood as exemplary and non-limiting, and not as requiring any particular hardware partition unless expressly stated otherwise.

In further embodiments, the appended subsystem-based implementations may continue to employ the previously described recognition coverage function and associated control relationships disclosed with reference to FIGS. 5-9. For example, charging control may continue to be performed using recognition-based scaling of charging current as described with reference to FIG. 6, discharging control may continue to be performed using recognition-based scaling of discharging current as described with reference to FIG. 7, and thermal-management control may continue to be performed using recognition-based adjustment of cooling-related setpoints as described with reference to FIG. 8. Likewise, adaptive updating may continue to be performed in a manner consistent with the adaptive update relationship described with reference to FIG. 9. In this regard, the appended embodiments do not displace the previously disclosed recognition framework, but instead may extend that framework by providing additional architectural organization, additional health-related outputs, additional adaptive operating-limit refinement, and additional deployment-specific implementations.

In some embodiments, state-of-charge, state-of-health, temperature, impedance, resistance, voltage, current, and/or other measured or derived battery parameters may be used not only for direct charge, discharge, and thermal control, but also for additional subsystem-specific evaluations. By way of example, one or more embodiments may generate a health-related score, degradation-related metric, alert signal, maintenance recommendation, replacement recommendation, or adaptive operating-limit update based on one or more measured or derived pack conditions. Such outputs may be used locally within the REBMS, stored in memory for later analysis, transmitted to an external controller or service platform, presented to an operator, or used to refine subsequent control intervals. In some embodiments, these additional functions may be executed concurrently with, before, after, or at a different cadence from the primary charge, discharge, and thermal-management control functions.

In further embodiments, the appended implementations may be applied across a range of battery chemistries, battery-pack topologies, and deployment environments. For example, the same overall recognition-based framework may be applied to lithium-ion, lithium iron phosphate, nickel manganese cobalt, nickel cobalt aluminum, lithium titanate, solid-state, nickel-metal hydride, lead-acid, second-life, hybrid, or mixed-storage systems, among others. Likewise, the disclosed architecture may be used in electric vehicles, bidirectional vehicle-to-grid environments, residential storage systems, commercial or industrial backup systems, grid-scale installations, portable electronics, and other rechargeable energy-storage applications. In some embodiments, chemistry-specific or application-specific operating limits may differ from one implementation to another, while the recognition-based control architecture and associated subsystem organization remain generally consistent.

In some embodiments, the control logic may be centralized within a single controller, such as RPC (130), or distributed among multiple controllers operating cooperatively. For example, measurement acquisition and low-latency actuator commands may be executed onboard a pack-level controller, while longer-horizon health analysis, fleet-level comparison, adaptive operating-limit optimization, warranty analytics, or predictive maintenance functions may be performed by one or more remote processors or cloud-based systems in communication through interface (150). In other embodiments, all computations may remain local to the battery-management controller. Thus, the appended embodiments are intended to encompass local, edge-assisted, distributed, and hybrid implementations, provided that the disclosed recognition-based control relationships are used to govern at least part of the battery-management process.

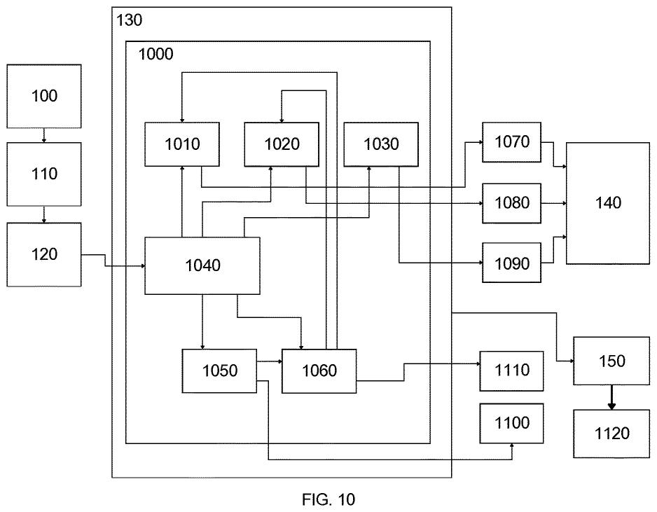

Accordingly, the following appended embodiments should be understood as providing additional detailed implementations of the previously described REBMS rather than replacing or redefining the earlier disclosure. The subsystem arrangements, health-related evaluations, adaptive operating-limit refinements, and deployment-specific variants described herein may be used alone or in any suitable combination with the previously described system architecture, recognition coverage function, charging control, discharging control, thermal-management control, adaptive updating, implementation details, and exemplary embodiments. In some embodiments, and as introduced in FIG. 10, the recognition-based functionality of the REBMS may be expressed as a recognition subsystem architecture (1000) comprising a plurality of cooperating functional subsystems within or associated with RPC (130), thereby providing a structured framework for implementing expanded recognition-based battery management features.

### 7. Recognition Subsystem Architecture

FIG. 10 illustrates an embodiment of a recognition subsystem architecture (1000) for the recognition-enhanced battery management system. In some embodiments, the recognition subsystem architecture (1000) may be implemented within, by, or in association with the Recognition Physics Controller (RPC) (130) of the previously described REBMS architecture. In this regard, the recognition subsystem architecture (1000) may be understood as an added organizational framework for the controller-side functionality already introduced with reference to FIG. 1, rather than as a replacement of the previously described battery-management system. Thus, the battery pack (100), sensor suite (110), metrology chain (120), RPC (130), power-stage actuators (140), and communications interface (150) may remain as previously described, while the appended embodiments further organize the recognition-based controller functionality into a plurality of cooperating subsystems, as shown in FIG. 10.

In some embodiments, operating-condition information from the battery pack (100) may be acquired by the sensor suite (110) and supplied, directly or through the metrology chain (120), to the RPC (130). Such operating-condition information may include, for example, one or more measured or derived indications of cell voltage, pack current, temperature, impedance, resistance, state-of-charge, state-of-health, or combinations thereof. In some embodiments, the metrology chain (120) may condition, digitize, synchronize, filter, normalize, and/or time-align the incoming measurements before the measurements are processed by the RPC (130). In other embodiments, one or more preprocessing operations may be performed elsewhere in the control stack, provided that the resulting operating-condition information is made available to the recognition subsystem architecture (1000) for further analysis and control generation.

In some embodiments, the recognition subsystem architecture (1000) may include a Recognition Charging Control subsystem (1010), a Recognition Discharging Control subsystem (1020), a Recognition Thermal Management subsystem (1030), a state-of-charge/state-of-health estimator (1040), a Recognition SOH Degradation Scoring subsystem (1050), and a Recognition Adaptive Parameter Tuning subsystem (1060). These components may be implemented as logical modules, firmware tasks, software services, hardware partitions, or combinations thereof. In some embodiments, two or more of the foregoing components may share one or more processors, memories, buses, scheduling resources, or safety-monitoring resources. In other embodiments, one or more such components may be distributed across separate controllers, coprocessors, programmable logic devices, or remote computing resources. Accordingly, the subsystem partition shown in FIG. 10 should be understood as exemplary and non-limiting, and one or more functions may be combined, subdivided, reordered, or replicated in particular implementations.

In some embodiments, the state-of-charge/state-of-health estimator (1040) may receive measurement-derived information from the sensor suite (110) and/or metrology chain (120) and may determine, estimate, update, or otherwise provide one or more state variables for use by other portions of the recognition subsystem architecture (1000). For example, the estimator (1040) may provide state-of-charge information, state-of-health information, temperature-related state information, impedance-related information, resistance-related information, trend information, or other battery-condition information to one or more of the Recognition Charging Control subsystem (1010), the Recognition Discharging Control subsystem (1020), the Recognition Thermal Management subsystem (1030), the Recognition SOH Degradation Scoring subsystem (1050), and the Recognition Adaptive Parameter Tuning subsystem (1060). In some embodiments, the estimator (1040) may also maintain historical state information, filtered state values, predicted values, confidence values, and/or trend values for use in current or future control intervals.

In some embodiments, the Recognition Charging Control subsystem (1010) may generate a charge-control command output (1070) for controlling one or more charging operations of the battery pack (100). For example, and consistent with the charging-control relationship described with reference to FIG. 6, the Recognition Charging Control subsystem (1010) may determine a charging-current command, charging-rate command, charging-enable command, charger duty-cycle command, or other charging-related control signal based on one or more inputs including state-of-charge information, one or more charge headroom values, one or more chemistry-dependent operating limits, and/or one or more outputs of the recognition coverage function. In some embodiments, the charge-control command output (1070) may be delivered to one or more power-stage actuators (140), charging circuits, charger interfaces, switching devices, gate drivers, or other charging hardware elements.

In some embodiments, the Recognition Charging Control subsystem (1010) determines a charge headroom value based on one or more state-of-charge limits. By way of example, the subsystem may determine a charge headroom as Hchg=SOCmax−SOC(t), where SOC(t) is a present state-of-charge estimate and SOCmax is an upper state-of-charge operating limit. In some embodiments, the subsystem determines a normalized input to the recognition coverage function as xchg=Hchg/max(SOCmax, ε), where ε is a small positive value used to avoid division by zero. In some embodiments, the subsystem applies the recognition coverage function to xchg to scale charging current or charging power, such that charging is gradually reduced as SOC(t) approaches SOCmax.

In some embodiments, the Recognition Discharging Control subsystem (1020) determines a discharge margin value based on one or more lower state-of-charge limits. By way of example, the subsystem may determine a discharge margin as Hdis=SOC(t)−SOCmin, where SOCmin is a lower state-of-charge operating limit. In some embodiments, the subsystem determines a normalized input to the recognition coverage function as xdis=Hdis/max((1−SOCmin), ε) or another suitable normalization. In some embodiments, the subsystem applies the recognition coverage function to xdis to scale discharging current, discharging power, or load allowance, such that discharging is gradually reduced as SOC(t) approaches SOCmin.

In some embodiments, the Recognition Discharging Control subsystem (1020) may generate a discharge-control command output (1080) for controlling one or more discharge operations of the battery pack (100). For example, and consistent with the discharging-control relationship described with reference to FIG. 7, the Recognition Discharging Control subsystem (1020) may determine a discharge-current command, power-delivery limit, load-management instruction, inverter command, discharge-enable signal, or other discharge-related control output based on one or more inputs including state-of-charge information, one or more lower operating bounds, one or more reserve margins, one or more predicted stress conditions, and/or one or more outputs of the recognition coverage function. In some embodiments, the discharge-control command output (1080) may be provided to one or more power-stage actuators (140), discharge switches, inverter stages, power-conversion circuits, contactors, or other discharge-related hardware.

In some embodiments, the Recognition Thermal Management subsystem (1030) may generate a thermal-management command output (1090) for controlling one or more thermal-management operations associated with the battery pack (100). For example, and consistent with the thermal-control relationship described with reference to FIG. 8, the Recognition Thermal Management subsystem (1030) may determine a cooling setpoint, fan-speed command, pump-speed command, valve-control signal, thermal derating instruction, thermal alarm threshold, or other temperature-management output based on one or more measured or estimated temperature values, one or more nominal operating temperatures, one or more temperature deviations, and/or one or more outputs of the recognition coverage function. In some embodiments, the thermal-management command output (1090) may be delivered to one or more power-stage actuators (140), thermal controllers, fans, pumps, coolant valves, refrigeration elements, heaters, or other thermal-management devices.

In some embodiments, the Recognition SOH Degradation Scoring subsystem (1050) may receive state-of-health information from the estimator (1040) and may determine a degradation score, health classification, maintenance indicator, replacement recommendation, warranty-related metric, diagnostic summary, or other health-related output corresponding to present and/or predicted battery condition. In some embodiments, the output of the Recognition SOH Degradation Scoring subsystem (1050) may include an alert, maintenance, or health output (1100). Such output may be stored locally, displayed to a user, transmitted to an external service platform, supplied to a fleet-management system, or used internally by one or more other control functions. In some embodiments, the Recognition SOH Degradation Scoring subsystem (1050) may operate on the same control cadence as one or more of the charging, discharging, and thermal-management subsystems. In other embodiments, the Recognition SOH Degradation Scoring subsystem (1050) may operate at a slower cadence based on accumulated operating history, cycle counts, daily summaries, service intervals, or other longer-horizon information.

In some embodiments, the Recognition SOH Degradation Scoring subsystem (1050) computes a scalar degradation score Dscore as a function of state-of-health, such that larger values indicate greater degradation. By way of example, the subsystem may compute Dscore=Fcov(1−SOH(t)), where SOH(t) is a present state-of-health estimate and Fcov(·) is the recognition coverage function. In this example, Dscore increases as SOH(t) decreases and may be used as a normalized degradation indicator for alerting, maintenance planning, operating-limit refinement, or warranty analytics.

In some embodiments, the subsystem classifies battery condition using one or more threshold bands applied to Dscore. By way of example only, the subsystem may designate a first band corresponding to normal operation when Dscore<T1, a second band corresponding to elevated attention when T1≤Dscore<T2, and a third band corresponding to service or replacement indication when Dscore≥T2, where T1 and T2 are configurable thresholds stored in memory. In some embodiments, the thresholds are selected per chemistry, application type, age, or duty cycle, and may be updated periodically or during service events.

In some embodiments, the Recognition Adaptive Parameter Tuning subsystem (1060) may receive state information from the estimator (1040) and/or degradation-related information from the Recognition SOH Degradation Scoring subsystem (1050), and may determine one or more updated operating limits, parameter refinements, control bounds, or configuration adjustments for future control intervals. For example, the Recognition Adaptive Parameter Tuning subsystem (1060) may generate an updated operating-limit output (1110) corresponding to one or more refined upper or lower operating bounds, state-of-charge limits, derating thresholds, charging margins, discharging margins, or other control parameters used by the Recognition Charging Control subsystem (1010) and/or the Recognition Discharging Control subsystem (1020). In some embodiments, such updates may supplement, extend, or refine the adaptive behavior previously described with reference to FIG. 9. In some embodiments, the Recognition Adaptive Parameter Tuning subsystem (1060) may operate periodically, such as daily, after a selected number of cycles, at service events, or in response to one or more detected degradation conditions, while one or more of the other subsystems operate at shorter control intervals.

In some embodiments, the Recognition Adaptive Parameter Tuning subsystem (1060) updates one or more operating limits using a windowed trend analysis of degradation-related information. By way of example, the subsystem may compute a trend value over a time window (e.g., a multi-hour, multi-day, or multi-cycle window), such as an SOH slope dSOH/dt, and may adjust one or more operating limits responsive to whether the trend indicates accelerated degradation under present operating conditions.

In some embodiments, the subsystem updates at least one of SOCmax or SOCmin according to an incremental step rule. By way of example, the subsystem may update an upper limit according to SOCmax, new=clamp(SOCmax, old−α·Gmax, SOCmax, min, SOCmax, max) and/or update a lower limit according to SOCmin, new=clamp(SOCmin, old+α·Gmin, SOCmin,min, SOCmin,max), where α is a positive step size, Gmax and Gmin are update terms derived from degradation-related information (e.g., a gradient estimate, a perturbation-based sensitivity estimate, or a trend-based penalty term), and clamp(·) enforces configured bounds stored in memory.

In some embodiments, the updated operating limits, thresholds, or parameter refinements produced by subsystem (1060) are stored in non-volatile memory and applied in subsequent control intervals. In some embodiments, updates are performed at a slower cadence than the real-time control loop (e.g., daily, per N cycles, or at service events), and include acceptance criteria that prevent updates unless sufficient operating history has been accumulated to support stable refinement.

In some embodiments, the Recognition Charging Control subsystem (1010), the Recognition Discharging Control subsystem (1020), and the Recognition Thermal Management subsystem (1030) may each receive information from the estimator (1040) and may generate their respective outputs independently, cooperatively, or in a coordinated manner. For example, one or more arbitration, prioritization, safety-bounding, fault-handling, or supervisory routines may be used to reconcile charge, discharge, and thermal outputs before such outputs are applied to hardware. In some embodiments, the system may impose one or more hard or soft bounds on the charge-control command output (1070), discharge-control command output (1080), and thermal-management command output (1090) before those outputs are issued to the power-stage actuators (140). In this manner, the recognition subsystem architecture (1000) may support coordinated control of electrochemical stress, power delivery, and thermal conditions while maintaining implementation flexibility.

In some embodiments, one or more outputs, states, alerts, scores, or parameter updates generated within the recognition subsystem architecture (1000) may also be communicated externally through an external analytics, fleet, or cloud interface (1120). For example, the external analytics, fleet, or cloud interface (1120) may exchange information with the communications interface (150) to support remote diagnostics, maintenance planning, fleet-level comparison, warranty analytics, software updates, operating-policy refinement, predictive maintenance, or cloud-assisted monitoring. In some embodiments, all subsystem computations may remain local to the RPC (130), and the external analytics, fleet, or cloud interface (1120) may be used only for telemetry or supervisory functions. In other embodiments, one or more longer-horizon analyses, historical trend analyses, or fleet-level optimizations may be performed remotely, while real-time charge, discharge, and thermal control remain local to the RPC (130).

In some embodiments, the recognition subsystem architecture (1000) may be implemented using embedded firmware executing on a microcontroller, processor, system-on-chip, digital signal processor, programmable logic device, application-specific integrated circuit, or equivalent computing platform. In some embodiments, the subsystem functions may execute serially, concurrently, periodically, asynchronously, event-driven, interrupt-driven, or according to a scheduled control loop. In some embodiments, the subsystem functions may share common code libraries, memory structures, lookup resources, filtering resources, safety logic, or communications paths. In other embodiments, one or more subsystem functions may be implemented in separate software containers, safety domains, hardware partitions, or remote execution environments. Thus, FIG. 10 should be understood as illustrating a functional subsystem architecture and associated information flows, rather than requiring any particular physical placement, programming model, or processor topology.

Accordingly, the recognition subsystem architecture (1000) shown in FIG. 10 provides a structured framework by which the previously described recognition-enabled battery-management functions may be organized into cooperating charging, discharging, thermal-management, health-scoring, and adaptive-tuning subsystems within or associated with the RPC (130). Through this arrangement, measurements obtained from the battery pack (100), sensor suite (110), and metrology chain (120) may be transformed into coordinated control outputs, health-related outputs, and adaptive operating-limit updates that are applied locally and/or communicated externally through the power-stage actuators (140) and communications interface (150), while remaining consistent with the broader REBMS architecture previously described herein.

### 8. Recognition Processing Pipeline

In some embodiments, the recognition-enhanced battery management system may operate according to a recurring recognition processing pipeline in which measured and derived battery information is acquired, processed, evaluated, and converted into one or more control outputs, health-related outputs, and adaptive parameter updates. With reference to FIG. 10, operating-condition information may be received from the sensor suite (110) and, in some embodiments, through the metrology chain (120), and may be supplied to the Recognition Physics Controller (RPC) (130) for evaluation within the recognition subsystem architecture (1000). In some embodiments, the recognition processing pipeline may be executed at fixed intervals, variable intervals, event-driven intervals, interrupt-driven intervals, or combinations thereof. For example, relatively fast control cycles may be used for charging, discharging, and thermal-management decisions, while slower cycles may be used for degradation scoring, trend analysis, and adaptive operating-limit refinement.

In some embodiments, the recognition processing pipeline may begin with acquisition of one or more measured battery parameters. Such parameters may include, by way of example, voltage, current, temperature, impedance, resistance, and other pack-level and/or cell-level measurements associated with the battery pack (100). In some embodiments, the sensor suite (110) may acquire measurements continuously, periodically, on demand, or in response to one or more operating events. In some embodiments, the metrology chain (120) may condition, digitize, calibrate, filter, normalize, synchronize, and/or time-align the acquired measurements prior to further processing. In other embodiments, one or more such operations may be performed within the RPC (130) or within another controller element in communication therewith. Derived values, such as estimated internal resistance, rate-of-change information, stress indicators, temperature gradients, usage-history indicators, or other inferred battery-condition values, may also be generated and supplied as inputs to later stages of the recognition processing pipeline.

In some embodiments, the acquired and/or derived information may be provided to the state-of-charge/state-of-health estimator (1040), which may compute, update, or otherwise determine one or more battery state variables for use by downstream subsystems. For example, the estimator (1040) may determine state-of-charge, state-of-health, one or more filtered or predicted state values, one or more trend values, confidence values, degradation indicators, and/or other battery-condition metrics. In some embodiments, the estimator (1040) may maintain both current-cycle values and historical values such that one or more subsystems of the recognition subsystem architecture (1000) may rely not only on instantaneous measured conditions, but also on previously observed operational history. In some embodiments, one or more outputs of the estimator (1040) may be updated during each control cycle, whereas other outputs may be updated at longer intervals.

In some embodiments, one or more measured, derived, and/or estimated inputs may then be evaluated using the recognition coverage function previously described with reference to FIG. 5. For example, one or more subsystem inputs may be normalized relative to one or more expected ranges, nominal operating values, stress thresholds, or learned control parameters and may be processed using one or more recognition-based relationships to determine how closely current battery conditions align with preferred, safe, efficient, or longevity-preserving operation. In this manner, the recognition coverage function of FIG. 5 may serve as a common evaluative kernel for multiple downstream subsystem decisions, while allowing different subsystems to apply the resulting information in different ways depending on whether charging, discharging, thermal regulation, degradation scoring, or adaptive tuning is being performed.

In some embodiments, the Recognition Charging Control subsystem (1010) may receive one or more relevant inputs from the estimator (1040) and/or from one or more outputs of the recognition coverage function and may generate a charge-control command output (1070). For example, with reference to FIGS. 6 and 10, the Recognition Charging Control subsystem (1010) may receive state-of-charge information, one or more upper operating bounds, one or more charge headroom indicators, one or more chemistry-specific charging constraints, and/or one or more stress-related indicators, and may determine a charging-current command, charging-rate command, charging enable/disable instruction, charger duty-cycle command, tapering instruction, or other charging-related control signal. In some embodiments, the charge-control command output (1070) may be supplied to one or more power-stage actuators (140), charger interfaces, switching devices, gate drivers, contactors, or related charging hardware for implementation during the current control interval.

In some embodiments, the Recognition Discharging Control subsystem (1020) may receive one or more relevant inputs from the estimator (1040) and/or from one or more outputs of the recognition coverage function and may generate a discharge-control command output (1080). For example, with reference to FIGS. 7 and 10, the Recognition Discharging Control subsystem (1020) may receive state-of-charge information, one or more lower operating bounds, reserve-margin information, predicted load conditions, one or more stress indicators, and/or one or more recognition-derived outputs, and may determine a discharge-current command, power-delivery limit, load-management instruction, inverter-control signal, discharge enable/disable instruction, or other discharge-related control action. In some embodiments, the discharge-control command output (1080) may be supplied to one or more power-stage actuators (140), inverters, contactors, switching stages, or power-conversion elements associated with discharge control.

In some embodiments, the Recognition Thermal Management subsystem (1030) may receive one or more temperature-related inputs from the estimator (1040), the sensor suite (110), and/or one or more outputs of the recognition coverage function and may generate a thermal-management command output (1090). For example, with reference to FIGS. 8 and 10, the Recognition Thermal Management subsystem (1030) may receive measured temperature values, estimated thermal trends, temperature deviations from one or more nominal operating temperatures, one or more pack stress indicators, and/or one or more recognition-derived outputs, and may determine a cooling setpoint, fan-speed command, pump-speed command, valve-control signal, thermal derating command, heater command, alarm threshold, or other thermal-management output. In some embodiments, the thermal-management command output (1090) may be delivered to one or more power-stage actuators (140), fans, pumps, coolant loops, valves, refrigeration devices, heaters, or other thermal-control hardware.

In some embodiments, the Recognition SOH Degradation Scoring subsystem (1050) may receive state-of-health information, degradation-related information, and/or historical battery-condition information and may compute one or more health-related outputs for use within the recognition processing pipeline. For example, the Recognition SOH Degradation Scoring subsystem (1050) may determine a degradation score, health classification, maintenance indicator, service recommendation, replacement recommendation, warranty-related metric, or other health-related measure representative of current and/or expected battery condition. In some embodiments, the Recognition SOH Degradation Scoring subsystem (1050) may generate an alert, maintenance, or health output (1100), which may be stored, displayed, transmitted, logged, or otherwise used by the system. In some embodiments, the Recognition SOH Degradation Scoring subsystem (1050) may operate on a slower cadence than one or more real-time control functions, such as by relying on accumulated cycling history, daily summaries, usage statistics, or multi-cycle trend analysis.

In some embodiments, the Recognition Adaptive Parameter Tuning subsystem (1060) may receive one or more inputs from the estimator (1040), the Recognition SOH Degradation Scoring subsystem (1050), and/or historical operating records and may determine one or more updated operating limits or control parameters for future use. For example, with reference to FIGS. 9 and 10, the Recognition Adaptive Parameter Tuning subsystem (1060) may evaluate state-of-health trends, degradation scores, prior-cycle behavior, stress-history information, observed thermal excursions, charge/discharge usage history, or other battery-performance information and may generate an updated operating-limit output (1110). In some embodiments, the updated operating-limit output (1110) may include one or more revised upper or lower state-of-charge limits, revised charging margins, revised discharging margins, revised derating thresholds, revised thermal thresholds, or other refined operating parameters that may be used by the Recognition Charging Control subsystem (1010), the Recognition Discharging Control subsystem (1020), the Recognition Thermal Management subsystem (1030), or combinations thereof in later control cycles. In some embodiments, the Recognition Adaptive Parameter Tuning subsystem (1060) may operate periodically, such as daily, after a selected number of cycles, upon a maintenance event, or in response to one or more identified degradation conditions, thereby supplementing and extending the adaptive behavior previously described with reference to FIG. 9.

In some embodiments, outputs generated by the Recognition Charging Control subsystem (1010), the Recognition Discharging Control subsystem (1020), and the Recognition Thermal Management subsystem (1030) may be coordinated before implementation. For example, one or more supervisory routines, arbitration routines, priority rules, safety checks, fault-monitoring functions, or bounded-output functions may be used to reconcile potentially competing control objectives prior to applying the charge-control command output (1070), the discharge-control command output (1080), and/or the thermal-management command output (1090) to the hardware. In some embodiments, hard limits, soft limits, fail-safe overrides, and/or fault-state restrictions may be imposed before one or more outputs are issued to the power-stage actuators (140). Thus, the recognition processing pipeline may support coordinated electrochemical, thermal, and power-management control while preserving system safety and implementation flexibility.

In some embodiments, one or more outputs of the recognition processing pipeline may be applied locally, stored for later use, transmitted externally, or reused during subsequent control intervals. For example, the charge-control command output (1070), discharge-control command output (1080), and thermal-management command output (1090) may be applied immediately to local hardware; the alert, maintenance, or health output (1100) may be logged or presented to an operator; and the updated operating-limit output (1110) may be stored in memory and used during later charging or discharging control cycles. In some embodiments, one or more states, alerts, health scores, trend indicators, and/or parameter updates may also be communicated through the external analytics, fleet, or cloud interface (1120) and communications interface (150) for remote diagnostics, analytics, maintenance planning, warranty support, or fleet-level optimization. Accordingly, the recognition processing pipeline described herein provides an operational framework by which measured battery conditions may be transformed into coordinated real-time control outputs, longer-horizon health-related outputs, and adaptive control refinements within the recognition subsystem architecture (1000) of FIG. 10.

### 9. Modality-Specific Implementations of the Recognition Subsystem Architecture.

In some embodiments, the recognition subsystem architecture (1000) shown in FIG. 10 may be applied across a variety of battery chemistries, battery capacities, pack topologies, and deployment modalities without requiring a different fundamental controller framework for each implementation. In this regard, the recognition-enhanced battery management system may retain the previously described overall architecture including the battery pack (100), sensor suite (110), metrology chain (120), Recognition Physics Controller (RPC) (130), power-stage actuators (140), and communications interface (150), while adapting one or more subsystem parameters, operating limits, or implementation details to the particular battery technology or application environment. Thus, the recognition subsystem architecture (1000) may provide a common organizational and control framework that is reusable across multiple battery-management contexts, while still permitting chemistry-specific, pack-specific, and application-specific tuning.

In some embodiments, the recognition subsystem architecture (1000) may be used with lithium-based battery chemistries, including lithium-ion chemistries and related variants. For example, the battery pack (100) may comprise lithium iron phosphate cells, nickel manganese cobalt cells, nickel cobalt aluminum cells, lithium titanate cells, solid-state cells, or combinations thereof. In such embodiments, one or more operating limits, recognition-function parameters, or subsystem-specific thresholds may be selected in accordance with the nominal voltage profile, thermal behavior, cycle-life characteristics, charge-acceptance behavior, discharge tolerance, or ageing tendencies associated with the selected chemistry. In some embodiments, the Recognition Charging Control subsystem (1010) may use chemistry-specific charging margins, tapering behavior, voltage ceilings, or current limits with reference to the charging-control behavior shown in FIG. 6, while the Recognition Discharging Control subsystem (1020) may use chemistry-specific discharge floors, reserve margins, or discharge derating thresholds with reference to FIG. 7. Likewise, the Recognition Thermal Management subsystem (1030) may apply chemistry-specific thermal targets, cooling thresholds, or thermal derating rules with reference to FIG. 8.

In some embodiments, the recognition subsystem architecture (1000) may also be implemented with battery chemistries other than lithium-based chemistries. For example, the battery pack (100) may comprise nickel-metal hydride cells, lead-acid cells, second-life battery modules, hybrid battery systems, mixed-chemistry storage assemblies, or other rechargeable electrochemical storage technologies. In such embodiments, the same general subsystem arrangement of FIG. 10 may still be used, even though the nominal operating windows, stress sensitivities, charge/discharge characteristics, or health-evaluation rules may differ from those used in lithium-based implementations. Accordingly, the appended embodiments should be understood as encompassing both lithium-based and non-lithium-based battery systems, provided that one or more recognition-based control relationships are used to evaluate battery condition and govern one or more charging, discharging, thermal-management, health-scoring, or adaptive-tuning functions.

In some embodiments, the recognition subsystem architecture (1000) may be implemented in electric-vehicle battery systems, vehicle-to-grid systems, residential energy-storage systems, commercial energy-storage systems, industrial backup systems, grid-scale storage installations, consumer-electronics power systems, portable electronics, robotics platforms, power tools, marine systems, aviation-related storage systems, and other rechargeable energy-storage applications. In some embodiments, the battery pack (100) may be configured as a traction pack, stationary storage array, modular rack-based storage unit, swappable battery assembly, portable battery enclosure, distributed battery cluster, or other pack format. In each of these examples, the subsystem framework may remain generally consistent, while the applicable charge/discharge rates, power-delivery objectives, thermal-management demands, degradation-monitoring priorities, and communications requirements may vary according to the intended use environment.

In some embodiments, chemistry-specific and application-specific differences may be reflected in one or more operating limits used within the recognition subsystem architecture (1000). For example, different embodiments may employ different nominal state-of-charge ranges, upper and lower state-of-charge limits, charging-rate ceilings, discharge-rate ceilings, power limits, current limits, thermal operating ranges, impedance thresholds, resistance thresholds, degradation-score thresholds, service thresholds, or adaptive tuning boundaries. In some embodiments, such values may be factory-defined, service-adjustable, learned over time, selected from one or more predefined chemistry profiles, or determined based on one or more deployment conditions. Thus, while the recognition subsystem architecture (1000) may remain common across many embodiments, the particular parameterization of the Recognition Charging Control subsystem (1010), the Recognition Discharging Control subsystem (1020), the Recognition Thermal Management subsystem (1030), the Recognition SOH Degradation Scoring subsystem (1050), and the Recognition Adaptive Parameter Tuning subsystem (1060) may vary according to chemistry, pack construction, or use case.

In some embodiments, the sensor suite (110) and/or metrology chain (120) may also vary according to the selected chemistry or deployment modality. For example, some embodiments may emphasize cell-level voltage sensing and pack-current sensing, while other embodiments may additionally include distributed temperature sensing, impedance sensing, resistance estimation, coolant-loop sensing, environmental sensing, isolation sensing, vibration sensing, or usage-pattern sensing. In some embodiments, one or more sensed parameters may be omitted, substituted, inferred, or estimated indirectly, provided that sufficient information is available for the recognition subsystem architecture (1000) to generate one or more useful control, health, and adaptive outputs. Accordingly, different sensor complements may be used in different battery products without requiring a departure from the general recognition-based subsystem framework.

In some embodiments, the Recognition Charging Control subsystem (1010), the Recognition Discharging Control subsystem (1020), and the Recognition Thermal Management subsystem (1030) may be configured differently for different battery types while still relying on the same overarching recognition-based control principles. For example, a first chemistry may tolerate relatively deep discharge operation but require more conservative charging behavior near a fully charged state, whereas a second chemistry may employ a wider practical charging region but tighter thermal controls. A stationary storage installation may prioritize long-term cycle-life preservation and thermal uniformity, while a vehicle application may place greater emphasis on transient power delivery, regenerative acceptance, or dynamic load response. Likewise, a portable electronics application may prioritize compact thermal control, lightweight sensing, and user-noticeable runtime extension. In each of these implementations, the recognition subsystem architecture (1000) may continue to process measured and derived battery information through the same subsystem arrangement of FIG. 10, while applying different chemistry-specific or modality-specific thresholds, margins, and optimization preferences.

In some embodiments, the Recognition SOH Degradation Scoring subsystem (1050) and the Recognition Adaptive Parameter Tuning subsystem (1060) may be particularly beneficial where ageing behavior diverges significantly across battery types, duty cycles, climates, user populations, or deployment fleets. For example, the same nominal battery chemistry may degrade differently in a high-throughput commercial fleet than in a lightly used residential-storage deployment, or may exhibit different health trajectories in cold-climate and hot-climate applications. In such embodiments, the Recognition SOH Degradation Scoring subsystem (1050) may generate degradation-related metrics, classifications, or maintenance outputs that reflect the specific ageing patterns of the corresponding application, and the Recognition Adaptive Parameter Tuning subsystem (1060) may generate updated operating-limit outputs (1110) that refine future charge, discharge, or thermal behavior in view of such observed differences. In this manner, the recognition subsystem architecture (1000) may support not only cross-chemistry adaptability, but also cross-environment and cross-fleet adaptation over time.

In some embodiments, one or more health-related outputs or maintenance-related outputs produced by the Recognition SOH Degradation Scoring subsystem (1050) may be stored, transmitted, or presented to a user or operator. For example, an alert, maintenance, or health output (1100) may be supplied to a local display, vehicle interface, service interface, remote dashboard, fleet-management system, or cloud-based analytics platform. In some embodiments, and with continued reference to FIG. 4, such outputs may include one or more user-facing indications of predicted state-of-health, maintenance condition, expected service timing, replacement timing, or other battery-condition information. Thus, the appended embodiments may support both internal controller-side adaptation and outward-facing reporting or maintenance workflows.

Accordingly, the recognition subsystem architecture (1000) of FIG. 10 should be understood as a modality-flexible and chemistry-flexible framework capable of supporting a broad range of rechargeable battery implementations. Whether used in lithium-based systems, non-lithium systems, vehicle applications, stationary storage environments, portable devices, or other battery-powered products, the disclosed subsystem arrangement may continue to provide coordinated recognition-based charging control, discharging control, thermal management, degradation scoring, and adaptive parameter tuning within the broader REBMS architecture previously described herein.

### 10. Computing and Deployment Implementations

In some embodiments, one or more portions of the recognition subsystem architecture (1000) may be implemented in software, firmware, hardware logic, or combinations thereof within, by, or in association with the Recognition Physics Controller (RPC) (130). With continued reference to FIGS. 1 and 10, the Recognition Charging Control subsystem (1010), the Recognition Discharging Control subsystem (1020), the Recognition Thermal Management subsystem (1030), the state-of-charge/state-of-health estimator (1040), the Recognition SOH Degradation Scoring subsystem (1050), and the Recognition Adaptive Parameter Tuning subsystem (1060) may be executed using one or more processing resources and one or more memory resources associated with the RPC (130) and/or with one or more connected computing platforms. In some embodiments, the subsystem architecture may be implemented as a set of computer-executable instructions stored in one or more non-transitory computer-readable media and executed by one or more processors to perform the recognition-based battery-management operations described herein. Thus, FIG. 10 may be understood as illustrating a functional architecture and information flow arrangement, rather than requiring any single fixed processor topology or software partition.

In some embodiments, the recognition subsystem architecture (1000) may be implemented using one or more embedded computing platforms, including, by way of example, a microcontroller, processor, system-on-chip, digital signal processor, programmable logic device, field-programmable gate array, application-specific integrated circuit, coprocessor, or combinations thereof. In some embodiments, the RPC (130) may comprise an embedded controller platform configured to execute battery-management firmware using a real-time scheduler, an interrupt-driven execution model, a real-time operating system, a bare-metal control loop, or another deterministic execution environment. In some embodiments, one or more subsystem functions may be implemented using an ARM-based controller platform, such as a Cortex-class microcontroller, while in other embodiments higher-performance or application-specific hardware may be used depending on pack size, deployment environment, computational demand, or system criticality. In some embodiments, one or more subsystem functions may be allocated across different processing domains, such as a primary control processor for charge, discharge, and thermal decisions, and one or more secondary processors or logic blocks for diagnostics, health analysis, adaptive tuning, communications, or safety supervision.

In some embodiments, volatile and/or non-volatile memory resources may be used to support execution of the recognition subsystem architecture (1000). For example, one or more memory devices may store executable instructions, calibration data, recognition-function parameters, operating limits, thermal thresholds, chemistry-specific configuration data, degradation metrics, cycle-history information, maintenance records, event logs, service records, learned control parameters, and/or adaptive operating-limit values. In some embodiments, one or more updated operating-limit outputs (1110) generated by the Recognition Adaptive Parameter Tuning subsystem (1060) may be stored for reuse in later control cycles. In some embodiments, one or more alert, maintenance, or health outputs (1100) generated by the Recognition SOH Degradation Scoring subsystem (1050) may likewise be stored in memory for subsequent retrieval, analysis, display, transmission, warranty processing, fleet comparison, or service diagnostics. In this manner, memory resources associated with the RPC (130) may support not only real-time control execution, but also historical analysis, trend evaluation, and adaptive refinement over time.

In some embodiments, the recognition subsystem architecture (1000) may be implemented using modular software and/or firmware structures. For example, the Recognition Charging Control subsystem (1010), Recognition Discharging Control subsystem (1020), Recognition Thermal Management subsystem (1030), state-of-charge/state-of-health estimator (1040), Recognition SOH Degradation Scoring subsystem (1050), and Recognition Adaptive Parameter Tuning subsystem (1060) may be implemented as separate software modules, tasks, threads, callable routines, services, libraries, safety partitions, containers, or combinations thereof. In some embodiments, such modules may share common data structures, mathematical libraries, filtering routines, diagnostic services, memory pools, safety logic, and/or communications resources. In other embodiments, one or more functions may be combined into a common executable component or subdivided into smaller software elements. Accordingly, the logical partitioning illustrated in FIG. 10 should not be understood as requiring any particular source-code organization, process boundary, or compilation boundary.

In some embodiments, one or more subsystem functions may communicate internally using shared memory, message queues, buses, interrupts, function calls, serialized data exchanges, or other interprocess or intermodule communication mechanisms. For example, the state-of-charge/state-of-health estimator (1040) may provide state values, predicted values, or trend information to the Recognition Charging Control subsystem (1010), the Recognition Discharging Control subsystem (1020), the Recognition Thermal Management subsystem (1030), the Recognition SOH Degradation Scoring subsystem (1050), and/or the Recognition Adaptive Parameter Tuning subsystem (1060) through one or more shared-memory structures or scheduled message transfers. In some embodiments, one or more subsystem outputs may be processed through supervisory logic, arbitration logic, and/or safety-bounding logic before implementation, thereby allowing a coordinated software pipeline to govern the application of the charge-control command output (1070), the discharge-control command output (1080), and the thermal-management command output (1090) to the power-stage actuators (140).

In some embodiments, the communications interface (150) and/or the external analytics, fleet, or cloud interface (1120) may support one or more wired and/or wireless data paths. By way of example, communications may be carried out using controller area network (CAN), CAN FD, Modbus, RS485, RS232, Ethernet, SPI, I2C, UART, USB, Bluetooth, Bluetooth Low Energy, Wi-Fi, cellular communication, MQTT, TCP/IP, UDP, cloud gateway protocols, proprietary telemetry protocols, or combinations thereof. In some embodiments, such communications paths may be used for local controller coordination, charger communication, inverter communication, service-tool access, diagnostics, firmware updates, fleet telemetry, cloud analytics, predictive maintenance, warranty monitoring, dashboard presentation, and/or remote policy distribution. In some embodiments, and with continued reference to FIG. 4, one or more health-related outputs, maintenance indicators, state estimates, degradation trends, or recommended service actions may be presented through a local display, operator dashboard, vehicle interface, remote maintenance console, or cloud-based analytics portal.

In some embodiments, the recognition subsystem architecture (1000) may be deployed in a local-only implementation in which substantially all control, estimation, scoring, and adaptive tuning operations are executed within the RPC (130) or another onboard controller associated with the battery pack (100). In other embodiments, the subsystem architecture may be implemented in an edge-assisted or distributed manner. For example, measurement acquisition, low-latency charge/discharge control, and thermal-management control may be executed locally, while longer-horizon degradation analysis, multi-pack comparison, maintenance planning, warranty analytics, chemistry-profile updates, adaptive policy refinement, and/or fleet-level optimization may be performed by one or more remote processors, service servers, enterprise systems, or cloud-based computing resources communicating through the communications interface (150) and/or the external analytics, fleet, or cloud interface (1120). In some embodiments, one or more remote computing resources may return updated configuration parameters, updated operating-limit policies, or refined analytics outputs for storage and later use by the local controller, while real-time actuation remains resident on the onboard platform.

In some embodiments, one or more software and/or firmware update mechanisms may be provided for the recognition subsystem architecture (1000). For example, executable instructions, recognition-function parameters, calibration data, chemistry-specific profiles, degradation-score thresholds, service policies, and/or adaptive tuning rules may be updated through a local service tool, a wired maintenance interface, a removable storage medium, a secure wireless session, or an over-the-air update path. In some embodiments, such updates may be cryptographically signed, authenticated, version-controlled, access-restricted, and/or verified prior to installation. In some embodiments, update procedures may be used not only to revise executable code, but also to provision or refresh one or more configuration values, operating bounds, service intervals, fleet policies, or learned-parameter baselines. In some embodiments, one or more adaptive parameter values may also be periodically synchronized to or from remote systems, consistent with the adaptive updating concepts described with reference to FIG. 9.

In some embodiments, the recognition subsystem architecture (1000) may incorporate one or more safety, reliability, and fault-management features. For example, watchdog timers, heartbeat monitors, fault-state transitions, bounded-output routines, fallback operating modes, sanity checks, range checks, plausibility checks, communication timeouts, redundant sensing checks, thermal protection checks, or controlled shutdown procedures may be used to preserve safe operation in the presence of faults, stale data, out-of-range conditions, degraded health states, or communication failures. In some embodiments, the charge-control command output (1070), the discharge-control command output (1080), and the thermal-management command output (1090) may each be subjected to one or more supervisory limits before implementation. In some embodiments, one or more faults may trigger reduced-performance modes, derated operating modes, conservative state-of-charge bounds, additional cooling measures, service alerts, or lockout states. In some embodiments, one or more such fault events may be logged for later diagnostics, service review, compliance reporting, or warranty processing.

In some embodiments, the recognition subsystem architecture (1000) may support logging, diagnostics, analytics, and serviceability features. For example, the system may log measurements, state estimates, control outputs, degradation scores, adaptive updates, maintenance indicators, update histories, fault records, and service interactions for later analysis. In some embodiments, such records may be used to support troubleshooting, field-service review, laboratory analysis, fleet comparison, predictive maintenance, warranty adjudication, chemistry-profile refinement, or operating-policy optimization. In some embodiments, remote or local service tools may access such records through the communications interface (150) and/or the external analytics, fleet, or cloud interface (1120). In some embodiments, the logged information may additionally support presentation of user-facing or operator-facing battery-condition information such as predicted health, expected maintenance timing, or recommended operating adjustments.

Accordingly, the computing and deployment implementations described herein demonstrate that the recognition subsystem architecture (1000) may be embodied in a wide variety of processor, memory, software, firmware, communications, and deployment configurations while remaining within the scope of the recognition-enhanced battery management system. Whether implemented in a single embedded controller, distributed across multiple onboard processing elements, coordinated with remote service platforms, or integrated with cloud-based fleet analytics, the subsystem architecture may continue to provide coordinated recognition-based charging control, discharging control, thermal management, degradation scoring, and adaptive parameter tuning within the broader REBMS framework described herein.

What is claimed is:

1. A battery-management system comprising:
(a) a battery pack including a plurality of battery cells;
(b) a sensor system configured to measure one or more operating parameters of the battery pack including voltage, current, temperature, and impedance;
(c) a metrology chain configured to receive signals from the sensor system and generate measurement data corresponding to the one or more operating parameters; and
(d) a Recognition Physics Controller configured to receive the measurement data, determine at least state-of-charge and state-of-health of the battery pack from the measurement data, evaluate a recognition coverage function based on at least the state-of-charge and the state-of-health, and generate one or more control signals to dynamically adjust at least one of charging current, discharging current, or a thermal-management set-point based on the recognition coverage function so as to reduce electrochemical stress in the battery pack.

2. The battery-management system of claim 1, wherein the one or more control signals include a charging-current control signal configured to adjust charging current supplied to the battery pack based on the recognition coverage function.

3. The battery-management system of claim 1, wherein the one or more control signals include a discharging-current control signal configured to adjust discharging current drawn from the battery pack based on the recognition coverage function.

4. The battery-management system of claim 1, wherein the one or more control signals include a thermal-management control signal configured to adjust operation of one or more cooling devices based on the recognition coverage function.

5. The battery-management system of claim 1, wherein the Recognition Physics Controller is further configured to adaptively update a recognition parameter based on state-of-health information of the battery pack and use the updated recognition parameter in a subsequent evaluation of the recognition coverage function.

6. The battery-management system of claim 5, wherein the updated recognition parameter is stored in memory and applied during a later control interval.

7. The battery-management system of claim 1, further comprising a communications interface configured to transmit telemetry associated with the battery pack and receive one or more signed updates for use by the Recognition Physics Controller.

8. A method of managing a battery pack, the method comprising:
(a) measuring, using one or more sensors, operating parameters of the battery pack including voltage, current, temperature, and impedance;
(b) determining state-of-charge and state-of-health from the measured operating parameters;
(c) evaluating a recognition coverage function using at least the determined state-of-charge and state-of-health; and
(d) adjusting at least one of charging current, discharging current, or a thermal-management set-point based on the evaluated recognition coverage function so as to reduce electrochemical stress in the battery pack.

9. The method of claim 8, further comprising:
(a) adjusting charging current based on the recognition coverage function;
(b) adjusting discharging current based on the recognition coverage function; and
(c) adjusting the thermal-management set-point based on the recognition coverage function.

10. The method of claim 8, further comprising adaptively updating a recognition parameter based on state-of-health information of the battery pack and using the updated recognition parameter in a subsequent evaluation of the recognition coverage function.

11. A battery-management system comprising:
(a) a battery pack including a plurality of battery cells;
(b) a sensor system configured to measure one or more operating parameters of the battery pack;
(c) a metrology chain configured to receive signals from the sensor system and generate measurement data corresponding to the one or more operating parameters; and
(d) a controller configured to receive the measurement data and implement:
(i) a Recognition Charging Control subsystem configured to generate a charge-control command output for controlling a charging operation of the battery pack;
(ii) a Recognition Discharging Control subsystem configured to generate a discharge-control command output for controlling a discharging operation of the battery pack;
(iii) a Recognition Thermal Management subsystem configured to generate a thermal-management command output for controlling a thermal-management operation associated with the battery pack;
(iv) a state-of-charge/state-of-health estimator configured to determine at least state-of-charge and state-of-health of the battery pack from the measurement data;
(v) a Recognition State-of-Health Degradation Scoring subsystem configured to generate a degradation-related output based on the state-of-health; and
(vi) a Recognition Adaptive Parameter Tuning subsystem configured to generate an updated operating-limit output for use in a later control interval.

12. The battery-management system of claim 11, wherein the state-of-charge/state-of-health estimator is configured to provide state information to the Recognition Charging Control subsystem, the Recognition Discharging Control subsystem, and the Recognition Thermal Management subsystem.

13. The battery-management system of claim 11, wherein the Recognition State-of-Health Degradation Scoring subsystem is configured to generate at least one of an alert output, a maintenance output, or a health output for storage, display, transmission, or use in battery-management control.

14. The battery-management system of claim 11, wherein the Recognition Adaptive Parameter Tuning subsystem is configured to generate the updated operating-limit output to include at least one updated state-of-charge limit for subsequent charging control or discharging control.

15. The battery-management system of claim 14, wherein the updated operating-limit output is stored in memory and used during the later control interval.

16. The battery-management system of claim 11, wherein the controller is further configured to coordinate the charge-control command output, the discharge-control command output, and the thermal-management command output using supervisory logic, arbitration logic, or safety-bounding logic before application to one or more power-stage actuators.

17. The battery-management system of claim 11, further comprising a communications interface configured to communicate with an external analytics, fleet, or cloud interface and provide to the external analytics, fleet, or cloud interface at least one of the degradation-related output or the updated operating-limit output.

18. A method of managing a battery pack, the method comprising:
(a) acquiring measurement data corresponding to one or more operating parameters of the battery pack;
(b) determining state-of-charge and state-of-health of the battery pack from the measurement data;
(c) generating a charge-control command output, a discharge-control command output, and a thermal-management command output based on the measurement data and the determined state-of-charge and state-of-health;
(d) generating a degradation-related output based on the determined state-of-health; and
(e) generating an updated operating-limit output for use in a later control interval.

19. The method of claim 18, wherein generating the updated operating-limit output comprises generating the updated operating-limit output based on at least one of state-of-health trend information or degradation information associated with the battery pack, and wherein the updated operating-limit output is used in a subsequent charging control interval or discharging control interval.

20. The method of claim 18, wherein at least one of the charge-control command output, the discharge-control command output, the thermal-management command output, the degradation-related output, or the updated operating-limit output is generated using a chemistry-specific operating bound or an application-specific operating bound.
